(19) United States
(12) Patent Application Publication
(10) Pub. No.: US 2007/0158847 A1
(43) Pub. Date: Jul. 12, 2007

(54) CIRCUIT BOARD DEVICE WITH FINE CONDUCTIVE STRUCTURE

(75) Inventor: Shih-Ping Hsu, Hsin-chu (TW)

Correspondence Address: ISHIMARU & ZAHRT LLP, 333 W. EL CAMINO REAL, SUITE 330, SUNNYVALE, CA, 94087, US

(73) Assignee: PHOENIX PRECISION TECHNOLOGY CORPORATION, Hsin-chu (TW)

(21) Appl. No.: 11/559,565

(22) Filed: Nov. 14, 2006

(30) Foreign Application Priority Data
Jan. 9, 2006 (TW) 095100715

(51) Int. Cl. H01L 23/52

(52) U.S. Cl. 257/758

(57) ABSTRACT

A circuit board device with a fine conductive structure is proposed. A circuit board having at least a circuit layer is provided and the circuit layer has at least one electrically conductive pad. At least one first dielectric layer is formed on surfaces of the circuit board and the circuit layer and has at least one opening to expose the electrically conductive pad of the circuit layer. At least a first fine conductive structure made of conductive material with high ductility is formed in the opening of the first dielectric layer and is electrically connected to the electrically conductive pad of the circuit layer. The top surface of the first fine conductive structure is higher than, level with or lower than the surface of the first dielectric layer. Moreover, a conductive pad may be further formed on the top surface of the first fine conductive structure. Since the first fine conductive structure is made of conductive material with high ductility, the stress strength of the first fine conductive structure is reinforced and the electrically connecting quality between layers of the circuit board is improved.

### BACKGROUND OF THE INVENTION

1. Field of the Invention

The present invention relates generally to circuit board devices with fine conductive structure, and more particularly to conductive via structure electrically connecting circuits between different layers of circuit boards.

2. Description of Related Art

Generally, conductive vias are used to electrically connect different circuit layers of a multi-layer circuit board. FIG. 1 shows a conventional conductive via structure. As shown in FIG. 1, a circuit board 10 having a first circuit layer 11 is provided. Therein, the first circuit layer 11 has at least an electrically conductive pad 110. A dielectric layer 12 is formed on the circuit board 10 having the first circuit layer 11, which has at least an opening 120 formed therein to expose the electrically conductive pad 110. Further, a second circuit layer 13 is formed on the dielectric layer 12 and a conductive via 131 is formed in the opening 120 so as to electrically connect the second circuit layer 13 to the electrically conductive pad 110 of the first circuit layer 11. The first circuit layer 11, the second circuit layer 13 and the conductive via 131 are generally made of copper.

However, with lead free requirement of the industry and demand for much smaller size of conductive vias, miniature circuit break often occurs inside conductive vias made of copper due to limited ductility and tensile strength of copper. Particularly, stacked vias of a multi-layer circuit board are much easier to crack if they are subjected to heat stress, which thus adversely affects the electrical connection between different circuit layers and reduces the product reliability.

Accordingly, there exists a strong need in the art for a fine conductive structure to improve electrical connection between different circuit layers of a circuit board.

### SUMMARY OF THE INVENTION

Accordingly, it is an objective of the present invention to provide a circuit board device with a fine conductive structure, through which stress strength of the fine conductive structure can be reinforced such that miniature circuit break in the fine conductive structure can be prevented.

It is another objective of the present invention to provide a circuit board device with a fine conductive structure, through which electrical connection quality between layers of the circuit board can be improved.

A further objective of the present invention is to provide a circuit board device with a fine conductive structure, through which stress strength of stacked conductive structure can be reinforced and electrical connection quality between layers of a circuit board can be improved.

In order to attain the objectives mentioned above and the others, a circuit board device with a fine conductive structure is proposed, which comprises: a circuit board having at least a circuit layer, the circuit layer having at least an electrically conductive pad; at least a first dielectric layer formed on surfaces of the circuit board and the circuit layer, wherein the first dielectric layer has at least an opening to expose the electrically conductive pad of the circuit layer; and at least a first fine conductive structure made of conductive material with high ductility formed in the opening of the first dielectric layer and electrically connected to the electrically conductive pad of the circuit layer.

The top surface of the first fine conductive structure can be higher than, level with or lower than the surface of the first dielectric layer.

The conductive material with high ductility is selected from the group consisting of Au, V, Ag, Al and alloy thereof.

In an embodiment, the electrically conductive pad has a recess portion formed corresponding in position to the opening so as to increase the bonding area between the electrically conductive pad and the first fine conductive structure.

In another embodiment, the circuit board device of the present invention further comprises a second dielectric layer formed on surfaces of the conductive pad and the first dielectric layer, the second dielectric layer having an opening to expose the conductive pad, a second fine conductive structure being formed in the opening and another conductive pad being formed on the top surface of the second fine conductive structure. Preferably, the first and second fine conductive structures are made of same material.

According to the present invention, since the fine conductive structure is made of conductive material with high ductility, stress strength of the fine conductive structure can be reinforced. As a result, the miniature circuit break in the prior art is prevented from occurring and the electrically connecting quality in the circuit board is improved.

### BRIEF DESCRIPTION OF DRAWINGS

FIG. 1 is a sectional view of a conventional fine conductive structure of a circuit board;

FIGS. 2A to 2D are sectional diagrams showing a fabrication method of a circuit board device with a fine conductive structure according to a first embodiment of the present invention;

FIGS. 2C-1, 2C-2 and 2C-3 are diagrams respectively showing different alternative structures of FIG. 2C;

FIGS. 2D-1, 2D-2 and 2D-3 are diagrams respectively showing different alternative structures of FIG. 2D;

FIGS. 3A and 3B are sectional diagrams of a circuit board device with a fine conductive structure according to a second embodiment of the present invention; and

FIG. 4 is a sectional diagram of a circuit board device with a fine conductive structure according to a third embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

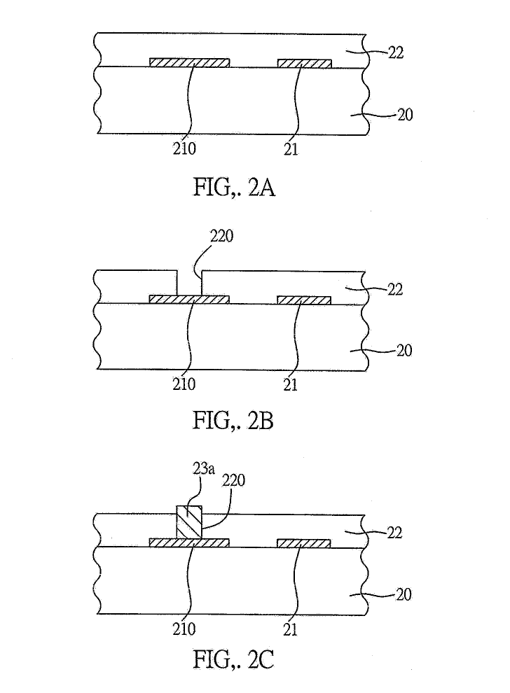

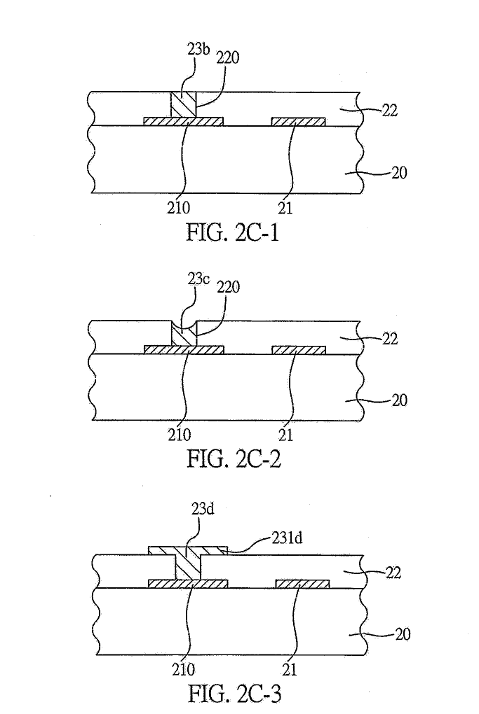

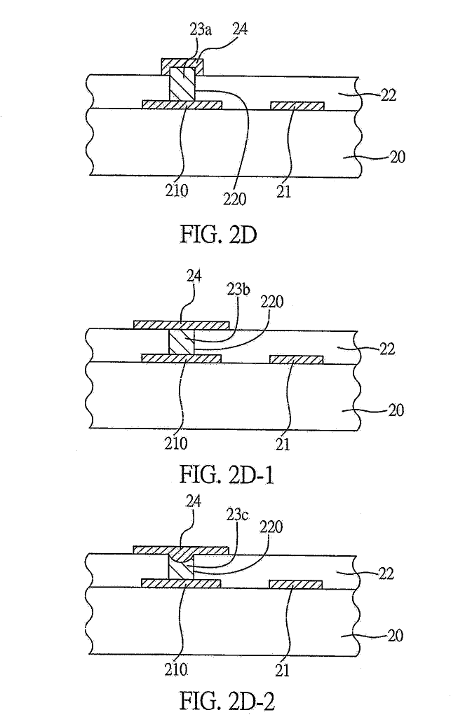

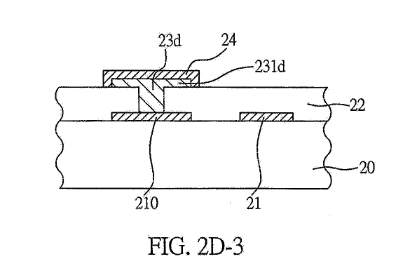

FIGS. 2A to 2D are sectional diagrams showing a fabrication method of a circuit board device with a fine conductive structure. In the present embodiment, the fine conductive structure has a conductive via structure.

Referring to FIG. 2A, a circuit board 20 having at least a circuit layer 21 is provided and a first dielectric layer 22 is formed on surfaces of the circuit board 20 and the circuit layer 21. The circuit layer 21 comprises at least one electrically conductive pad 210. The circuit layer 21 can be made of copper. The first dielectric layer 22 can be made of photosensitive or non-photosensitive organic resin or epoxy resin comprising glass fiber, such as ABF (Ajinomoto Build-up Film), BCB (Benzocyclo-buthene), LCP(Liquid Crystal Polymer), PI(Polyimide), PPE(Polyphenylene Ether), PTFE(Polytetrafluoroethylene), FR4, FR5, BT (Bismaleimide Triazine) and Aramide.

Referring to FIG. 2B, an opening 220 is formed in the first dielectric layer 22 corresponding in position to the electrically conductive pad 210 of the circuit layer 21 such that the electrically conductive pad 210 can be exposed from the opening 220.

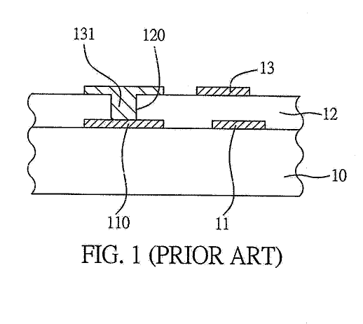

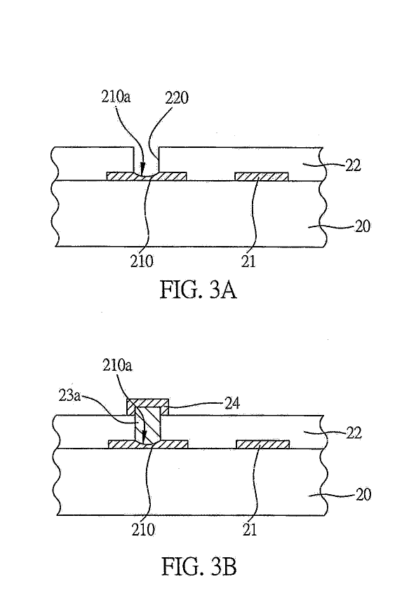

Referring to FIG. 2C, a first fine conductive structure 23a is formed in the opening 220 of the first dielectric layer 22 and electrically connected to the electrically conductive pad 210 of the circuit layer 21. The top surface of the first fine conductive structure 23a is higher than the surface of the first dielectric layer 22 in the present embodiment. Alternatively, as shown in FIG. 2C-1, the top surface of the first fine conductive structure 23b can be level with the surface of the first dielectric layer 22, or as shown in FIG. 2C-2, the top surface of the first fine conductive structure 23c can be lower than the surface of the first dielectric layer 22. Alternatively, as shown in FIG. 2C-3, the first fine conductive structure 23d has a protruding portion 231d extending from the top surface thereof and covering a part of the surface of the first dielectric layer 22. The first fine conductive structures 23a to 23d are made of conductive material with high ductility. Preferably, the conductive material is selected from the group consisting of Au, V, Ag, Al and alloy thereof.

Referring to FIGS. 2D, 2D-1, 2D-2 and 2D-3, a conductive pad 24 is respectively formed on the top surface of the first fine conductive structures 23a to 23d and covers the first fine conductive structures 23a to 23d for further electrical connection. Preferably, the conductive pad 24 is made of copper.

Through the above fabrication method, a circuit board device with a fine conductive structure is obtained, which comprises: a circuit board 20 having at least a circuit layer 21, the circuit layer having at least an electrically conductive pad 210; at least a first dielectric layer 22 formed on surfaces of the circuit board 20 and the circuit layer 21, wherein the first dielectric layer 22 has at least an opening 220 to expose the electrically conductive pad 210 of the circuit layer 21; and at least a first fine conductive structure 23a, 23b, 23c or 23d made of conductive material with high ductility formed in the opening 220 of the first dielectric layer 22 and electrically connected to the electrically conductive pad 210 of the circuit layer 21. The top surface of the first fine conductive structure such as 23a, 23b or 23d is higher than, level with or lower than the surface of the first dielectric layer 22. The first fine conductive structure may also has a protruding portion 231d extending from the top surface thereof and covering a part of the surface of the first dielectric layer 22.

The circuit board device may further comprise a conductive pad 24 formed on the top surface of the first fine conductive structures 23a to 23d and covers the first fine conductive structures 23a to 23d for further electrical connection. The conductive pad 24 can be made of copper.

It should be noted that although the circuit board device of the present embodiment comprises a conductive pad, it is not limited thereto. In other embodiments, it may not be necessary to form a conductive pad in a circuit board device.

### Second Embodiment

FIGS. 3A and 3B are sectional diagrams of a circuit board device with a fine conductive structure according to a second embodiment of the present invention. The difference of the circuit board device of the present embodiment from that of the first embodiment is the electrically conductive pad has a recess portion formed on surface thereof so as to increase bonding area between the electrically conductive pad and the fine conductive structure.

Referring to FIG. 3A, the first dielectric layer 22 is formed on surface of the circuit board 20 having the circuit layer 21 and the opening 220 is formed in the first dielectric layer 22 corresponding in position to the electrically conductive pad 210 of the circuit layer 21. The electrically conductive pad 210 has a recess portion 210a formed on the surface thereof. The recess portion 210a can have such as an arc-shaped recess 210a not penetrating the electrically conductive pad 210.

Referring to FIG. 3B, the first fine conductive structure 23a is formed in the opening 220 of the first dielectric layer 22 and filling the recess portion 210a of the electrically conductive pad 210 such that the bonding area between the first fine conductive structure 23a and the electrically conductive pad 210 can be increased via the recess portion 210a, thereby obtaining a preferable bonding strength therebetween.

### Third Embodiment

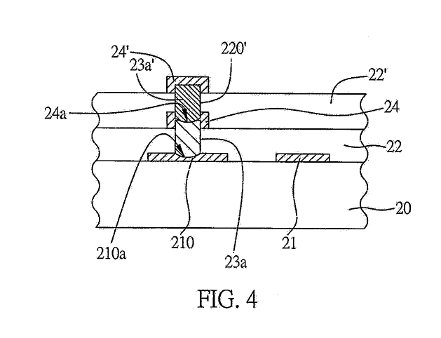

FIG. 4 shows a circuit board device according to a third embodiment of the present invention. In the present embodiment, the fine conductive structure is formed inside a multi-layer circuit board.

As shown in FIG. 4, a second dielectric layer 22′ is further formed on surfaces of the conductive pad 24 and the dielectric layer 22. The second dielectric layer 22′ has an opening 220′ formed therein to expose the conductive pad 24. A second fine conductive structure 23a′ is formed in the opening 220′ and electrically connected to the conductive pad 24. The top surface of the second fine conductive structure 23a′ is higher than the surface of the second dielectric layer 22′. In addition, another conductive pad 24′ is formed on the top surface of the second fine conductive structure 23a′. Thus, a circuit board having multi-layer circuit is formed. Also, the first and second fine conductive structures 23, 23a′ connected in series form a stacked via structure so as to obtain a preferred bonding connection.

A recess portion 24a such as an arc-shaped blind opening may further be formed on surface of the conductive pad 24 so as to increase bonding area between the conductive pad 24 and the second fine conductive structure 23a′, thereby increasing bonding force therebetween.

Moreover, an appropriate material of the fine conductive structure can be selected according to the need. For example, in a high density circuit area, gold can be selected as material of the fine conductive structure, while copper can be used to form the fine conductive structure in a low density circuit area.

According to the present invention, the fine conductive structure is made of conductive material with high ductility and thus stress strength of the fine conductive structure is reinforced. As a result, the miniature circuit break in the prior art is prevented from occurring and the electrically connecting quality of the circuit board is improved.

The above-described descriptions of the detailed embodiments are only to illustrate the preferred implementation according to the present invention, and it is not to limit the scope of the present invention, i.e., other changes still can be implemented in the present invention. For example, for those circuit boards that have very similar component layout, sometimes a single masking board may be used by simply blocking those unwanted openings. Accordingly, all modifications and variations completed by those with ordinary skill in the art should fall within the scope of present invention defined by the appended claims.

What is claimed is:

1. A circuit board device with a fine conductive structure, comprising:
a circuit board having at least a circuit layer, the circuit layer having at least an electrically conductive pad;
at least a first dielectric layer formed on surfaces of the circuit board and the circuit layer, wherein the first dielectric layer has at least an opening to expose the electrically conductive pad of the circuit layer; and
at least a first fine conductive structure made of conductive material with high ductility formed in the opening of the first dielectric layer and electrically connected to the electrically conductive pad of the circuit layer.

2. The circuit board device of claim 1, wherein the top surface of the first fine conductive structure is higher than, level with or lower than the surface of the first dielectric layer.

3. The circuit board device of claim 1, wherein the first fine conductive structure has a protruding portion extending from the top surface of the first fine conductive structure and covering a part of the surface of the first dielectric layer.

4. The circuit board device of claim 1, further comprising a conductive pad formed on the top surface of the first fine conductive structure.

5. The circuit board device of claim 4, wherein the conductive pad is made of copper.

6. The circuit board device of claim 4, further comprising a second dielectric layer formed on surfaces of the conductive pad and the first dielectric layer, the second dielectric layer having an opening to expose the conductive pad, a second fine conductive structure being formed in the opening and another conductive pad being formed on the top surface of the second fin e conductive structure.

7. The circuit board device of claim 6, wherein the top surface of the second fine conductive structure is higher than, level with or lower than the surface of the second dielectric layer.

8. The circuit board device of claim 6, wherein the second fine conductive structure has a protruding portion extending from the top surface of the second fine conductive structure and covering a part of the surface of the second dielectric layer.

9. The circuit board device of claim 1, wherein the electrically conductive pad of the circuit layer corresponds in position to the opening of the first dielectric layer.

10. The circuit board device of claim 9, wherein the electrically conductive pad has a recess portion formed corresponding in position to the opening so as to increase the bonding area between the electrically conductive pad and the first fine conductive structure.

11. The circuit board device of claim 1, wherein the conductive material with high ductility is selected from the group consisting of Au, V, Ag, Al and alloy thereof.
